(19) United States
(12) Patent Application Publication
(10) Pub. No.: US 2009/0309857 A1
(43) Pub. Date: Dec. 17, 2009

(54) Operational amplifter circuit, and driving method of liquid crystal display using the same

(75) Inventor: Kouichi Nishimura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/457,251

(22) Filed: Jun. 4, 2009

(30) Foreign Application Priority Data
Jun. 17, 2008 (JP) 157812/2008

(51) Int. Cl. G09G 5/00; H03F 3/45

(52) U.S. Cl. 345/205; 330/253; 330/257

(57) ABSTRACT

A small-offset operational amplifier circuit with a simple circuit architecture is provided. An operational amplifier circuit includes: differential pair sections (MN1 and MN2, MP1 and MP2); a first switch section (SG3); folded cascode-connected current mirror circuit sections (MP3 to MP6, MN3 to MN6); a second switch section (SG1 and SG2); and a buffer amplifier (BA), wherein the operational amplifier circuit interlockingly switches between the first switch section (SG3) and the second switch section (SG1 and SG2) so as to spatially disperse offset voltage and equivalently cancel offset.

### BACKGROUND OF THE INVENTION

1. Field of the Invention

The present invention relates to an operational amplifier circuit, and more particularly, to an operational amplifier circuit that drives a capacitive load.

2. Description of the Related Art

Conventionally, operational amplifiers have been typically made up of bipolar transistors. However, recently, given the need for integration with a MOS (metal oxide semiconductor) circuit and demands for low power, an increasing number of operational amplifiers are also configured of MOS transistors. When configuring an operational amplifier with MOS transistors, the use of analog characteristics specific to MOS transistors may enable the adoption of a circuit architecture different from that of an operational amplifier made up of bipolar transistors.

One field of application of MOS transistor-configured operational amplifiers is the TFT LCD (thin film transistor liquid crystal display) driver LSI (large scale integrated circuit). The LCD driver LSI is mounted with a plurality of operational amplifier circuits having a voltage follower configuration as an output buffer circuit or a γ correction gray scale power supply. Such operational amplifiers require a circuit having a small offset voltage difference between the respective operational amplifiers. This is due to the fact that given the characteristics of TFT LCD, even a voltage difference of 10 mV will be recognized as a different tone gradation by the human eye. Consequently, a MOS operational amplifier with an extremely small offset voltage is required in this field.

FIG. 1 is a circuit diagram showing a configuration example of an operational amplifier applied to drive a graphic display device. This operational amplifier is the amplifier disclosed in Japanese Patent Laid-Open No. 2006-319921. The operational amplifier is provided with: N-channel MOS transistors MN1 to MN6; P-channel MOS transistors MP1 to MP6; switches S1 to S8; constant current sources I1 to I3; constant voltage sources V1 and V2; and an output buffer amplifier BA. The operational amplifier is provided with: a non-inversion input node In+; an inversion input node In−; and an output node Vout. The operational amplifier shown in FIG. 1 has a voltage follower configuration in which the output node Vout is connected to the inversion input node In−.

The N-channel MOS transistors MN1 and MN2 form an N-channel receiving differential pair.

An input pair of the N-channel receiving differential pair is respectively connected via switches S5 and S6 to the non-inversion input node In+ and the output node Vout. The P-channel MOS transistors MP1 and MP 2 form a P-channel receiving differential pair. In a similar manner, an input pair of the P-channel receiving differential pair is respectively connected via switches S7 and S8 to the non-inversion input node In+ and the output node Vout.

Respective gates of the P-channel MOS transistors MP3 and MP4 are commonly connected to each other and are further connected to the constant voltage source V1. Respective sources of the P-channel MOS transistors MP3 and MP4 are connected via the switch S3 to drains of the P-channel MOS transistors MP5 and MP6. A drain of the P-channel MOS transistor MP3 is connected to commonly-connected gates of the P-channel MOS transistors MP5 and MP6.

Respective sources and respective gates of the P-channel MOS transistors MP5 and MP6 are commonly connected to each other, and the sources are further connected to a positive power supply voltage VDD. The P-channel MOS transistors MP5 and MP6 function as an active load of a folded cascode connection.

Respective gates of the N-channel MOS transistors MN3 and MN4 are commonly connected to each other and are further connected to the constant voltage source V2. Respective sources of the N-channel MOS transistors MN3 and MN4 are connected via the switch S4 to drains of the N-channel MOS transistors MN5 and MN6. A drain of the N-channel MOS transistor MN3 is connected to commonly-connected gates of the N-channel MOS transistors MN5 and MN6.

Respective sources and respective gates of the N-channel MOS transistors MN5 and MN6 are commonly connected to each other, and the sources are further connected to a negative power supply voltage VSS. The N-channel MOS transistors MN5 and MN6 function as an active load of a folded cascode connection.

The switch S1 switches the connection destinations of respective drains of the N-channel MOS transistors MN1 and MN2. The switch S2 switches the connection destinations of respective drains of the P-channel MOS transistors MP1 and MP2.

The switch S3 is connected between the respective drains of the P-channel MOS transistors MP5 and MP6 and the respective sources of the P-channel MOS transistors MP3 and MP4. In other words, the switch S3 switches the connections between the drain of the P-channel MOS transistor MP5 and the respective sources of the P-channel MOS transistors MP3 and MP4. In addition, the switch S3 switches the connections between the drain of the P-channel MOS transistor MP6 and the respective sources of the P-channel MOS transistors MP3 and MP4.

The switch S4 is connected between the respective drains of the N-channel MOS transistors MN5 and MN6 and the respective sources of the N-channel MOS transistors MN3 and MN4. In other words, the switch S4 switches the connections between the drain of the N-channel MOS transistor MN5 and the respective sources of the N-channel MOS transistors MN3 and MN4. In addition, the switch S4 switches the connections between the drain of the N-channel MOS transistor MN6 and the respective sources of the N-channel MOS transistors MN3 and MN4.

A common node of the switch S5 is connected to the input node In+ of the amplifier. A make node of the switch S5 is connected to a gate of the N-channel MOS transistor MN1 while a break node thereof is connected to a gate of the N-channel MOS transistor MN2. A common node of the switch S6 is connected to the output node Vout of the amplifier. A break node of the switch S6 is connected to the gate of the N-channel MOS transistor MN1 while a make node thereof is connected to the gate of the N-channel MOS transistor MN2. In other words, the switch S5 switches connection destinations of a non-inversion input signal of the N-channel receiving differential pair while the switch S6 switches connection destinations of an inversion input signal of the N-channel receiving differential pair.

A common node of the switch S7 is connected to the input node In+ of the amplifier. A make node of the switch S7 is connected to a gate of the P-channel MOS transistor MP1 while a break node thereof is connected to a gate of the P-channel MOS transistor MP2. A common node of the switch S8 is connected to the output node Vout of the amplifier. A break node of the switch S8 is connected to the gate of the P-channel MOS transistor MP1 while a make node thereof is connected to the gate of the P-channel MOS transistor MP2. In other words, the switch S7 switches connection destinations of a non-inversion input signal of the P-channel receiving differential pair while the switch S8 switches connection destinations of an inversion input signal of the P-channel receiving differential pair.

The constant current source I1 is connected between commonly connected sources of the N-channel MOS transistors MN1 and MN2 and the negative power supply voltage VSS. The constant current source I2 is connected between commonly connected sources of the P-channel MOS transistors MP1 and MP2 and the positive power supply voltage VDD.

The constant current source I3 is a floating current source. One end of the constant current source I3 is commonly connected to a node to which the drain of the P-channel MOS transistor MP3 and the gates of the P-channel MOS transistors MP5 and MP6 are connected. The other end thereof is commonly connected to a node to which the drain of the N-channel MOS transistor MN3 and the gates of the N-channel MOS transistors MN5 and MN6 are connected.

The constant voltage source V1 is connected between the commonly connected gates of the P-channel MOS transistors MP3 and MP4 and the positive power supply voltage VDD. The constant voltage source V2 is connected between the commonly connected gates of the N-channel MOS transistors MN3 and MN4 and the negative power supply voltage VSS.

With the output buffer amplifier 2, the drain of the P-channel MOS transistor MP4 and the drain of the N-channel MOS transistor MN4 are respectively connected to two input nodes thereof and the output buffer amplifier 2 functions as an output buffer. An output of the output buffer amplifier 2 is connected to the output node Vout to be fed back to the inversion input node.

Operations of the operational amplifier shown in FIG. 1 will now be described. The switches S1, S5, and S6 operate interlockingly as a switch group SW1 and are simultaneously driven. In addition, the switches S2, S7, and S8 operate interlockingly as a switch group SW2 and are simultaneously driven. The switches S3 and S4 are respectively independently driven as switch groups SW3 and SW4. In other words, drive patterns can be classified into the four switch groups.
(1) Switch Group SW1 (S1, S5, S6),
(2) Switch Group SW2 (S2, S7, S8),
(3) Switch Group SW3 (S3), and
(4) Switch Group SW4 (S4).

The switch groups SW1 to SW4 can respectively be driven independently of each other. As an example, a case of switching the switch group SW1 will now be described. Let us assume that an offset voltage generated due to a mismatch factor between the N-channel MOS transistors MN1 and MN2 constituting a differential pair is denoted by Vos(N-differential), while an aggregate total of offset voltage caused by other factors is denoted by VOS(excluding N-differential). If input voltage is denoted by VIN, then output voltage Vo can be expressed as Vo=VIN+VOS(excluding N-differential)±Vos(N-differential).

In this case, “±” indicates that switching the switch group SW1 results in an output whose polarity is reversed. Therefore, when switching the switch group SW1 and calculating a time average, the term ±Vos(N-differential) is cancelled out and becomes 0. In other words, by switching the switch group SW1, the influence of an offset voltage generated due to the mismatch factor between the N-channel MOS transistors MN1 and MN2 can be eliminated.

Similarly, when switching the switch group SW2, assuming that an offset voltage generated due to a mismatch factor between the P-channel MOS transistors MP1 and MP2 constituting a differential pair is denoted by Vos(P-differential), an aggregate total of offset voltage caused by other factors by VOS(excluding P-differential), and an input voltage by VIN, then output voltage Vo can be expressed as Vo=VIN+VOS(excluding P-differential)±Vos(P-differential).

The same reasoning applies to the switching of the switch groups SW3 and SW4, where an offset voltage is outputted after having its polarity reversed depending on the state of the switch. By turning ON/OFF (switching) and averaging the switch groups SW1 to SW4, the offset voltages generated by the respective element groups are cancelled out and become zero. Therefore, since all of the switches are collectively turned ON/OFF, all offset voltages are averaged and become zero. As a result, the influence of offset voltages is reduced.

Since two states of ON/OFF exist for each of the four switch groups, the total number of possible states is 2⁴, or 16. However, all of these states need not necessarily be created. For example, a total of 8 states are realized by interlocking the switch groups SW1 and SW2 so as to assume the three switch groups of (SW1+SW2), SW3, and SW4. Alternatively, switching may be performed between the two states of ON/OFF by interlocking all of the switch groups. As shown, the respective switch groups may be interlocked in any combination.

As shown, an offset-cancelling operational amplifier circuit can be accommodated by the circuit shown in FIG. 1 without incident insofar as the circuit is designed exactly as described above. However, in actual application, employing a method other than creating and sequentially progressing through the 16 states described above such as interlocking all of the switches to realize a simple two-way arrangement and performing offset cancellation repeating the two states results in a redundant circuit architecture. This leads to increases in cost. In addition, unnecessary elements cause an increase in parasitic capacitance and, in turn, to insufficient phase margins.

While measures such as increasing idling current are performed in response to such problems, performing such measures increases power consumption.

The present invention provides a small-offset operational amplifier circuit with a simple circuit architecture. In particular, the present invention provides an operational amplifier circuit suitable for an LCD driver that is a typical LSI in the imaging field.

### SUMMARY OF THE INVENTION

Measures for solving the problems presented above will now be described using reference numerals and characters used in the [DETAILED DESCRIPTION OF THE PREFERRED EMBODIMENTS]. The reference numerals and characters have been added to demonstrate the correspondence between the [CLAIMS] and the [DETAILED DESCRIPTION OF THE PREFERRED EMBODIMENTS]. However, it should be noted that the reference numerals and characters are not to be used to interpret the technical scope of the present invention described in the [CLAIMS].

According to an aspect of the present invention, an operational amplifier circuit is provided with: differential pair sections (MN1 and MN2, MP1 and MP2); a first switch section (SG3); folded cascode-connected current mirror circuit sections (MP3 to MP6, MN3 to MN6); a second switch section (SG1 and SG2); and a buffer amplifier (BA), wherein the operational amplifier circuit interlockingly switches between the first switch section (SG3) and the second switch section (SG1 and SG2) so as to spatially disperse offset voltage and equivalently cancel offset. The differential pair sections (MN1 and MN2, MP1 and MP2) receive an input signal inputted from a signal input node (In+) and an output signal outputted from a signal output node (Vout) as differential signals. The first switch section (SG3) interchanges the input signal and the output signal and connects the signals to the differential pair sections (MN1 and MN2, MP1 and MP2). The folded cascode-connected current mirror circuit sections (MP3 to MP6, MN3 to MN6) become active loads of the differential pairs (MN1 and MN2, MP1 and MP2). The current mirror circuit sections (MP3 to MP6, MN3 to MN6) are provided with: load transistor groups (MP5 and MP6, MN5 and MN6) that function as active loads of folded cascode connections; and bias transistor groups (MP3 and MP4, MN3 and MN4) to which a bias voltage is applied. The second switch section (SG1 and SG2) switches connections with the load transistor groups (MP5 and MP6, MN5 and MN6) and the bias transistor groups (MP3 and MP4, MN3 and MN4). The buffer amplifier (BA) receives a signal outputted from the current mirror circuit sections (MP3 to MP6, MN3 to MN6) and outputs an output signal (Vout).

A driving method of a liquid crystal display according to another aspect of the present invention is a driving method that drives a liquid crystal display using the operational amplifier circuit described above, wherein the method is provided with a first connection step and a second connection step, and repeats the first step and the second step at the same intervals so as to partially disperse offset voltage and equivalently cancel offset. In the first connection step, an input signal is inputted to a first input node of a differential pair section and an output signal is inputted to a second input node of the differential pair section. In addition, a first load transistor group among the load transistor groups and a first bias transistor group among the bias transistor groups are connected to each other, and a second load transistor group among the load transistor groups and a second bias transistor group among the bias transistor groups are connected to each other. In the second connection step, an output signal is inputted to the first input node of the differential pair section and an input signal is inputted to the second input node of the differential pair section. The first load transistor group among the load transistor groups and the second bias transistor group among the bias transistor groups are connected to each other, and the second load transistor group among the load transistor groups and the first bias transistor group among the bias transistor groups are connected to each other.

According to the present invention, a small-offset operational amplifier circuit having a simple circuit architecture can be provided. The operational amplifier circuit is particularly suitable for an LCD driver that is a typical LSI in the imaging field.

### BRIEF DESCRIPTION OF THE DRAWINGS

FIG. 1 is a circuit diagram showing a configuration example of a conventional operational amplifier with spatial offset cancellation;

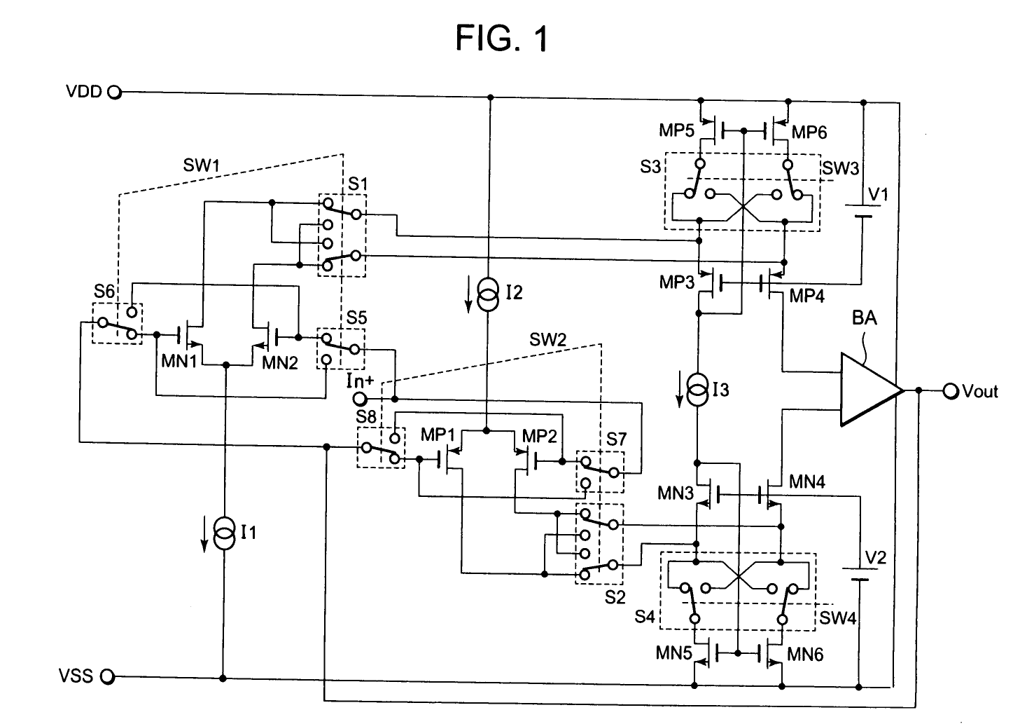

FIG. 2 is a block diagram showing a configuration example of a liquid crystal display according to an embodiment of the present invention;

FIG. 3 is a block diagram showing an equivalent circuit of a differential amplifier according to a first embodiment of the present invention;

FIG. 4 is a diagram showing a modification of a configuration of a switch section of the equivalent circuit shown in FIG. 3;

FIG. 5 is a block diagram showing an equivalent circuit of a differential amplifier according to a second embodiment of the present invention;

FIG. 6 is a block diagram showing an equivalent circuit of a differential amplifier according to a third embodiment of the present invention;

FIG. 7 is a block diagram showing an equivalent circuit of a differential amplifier according to a fourth embodiment of the present invention;

FIGS. 8A to 8D are diagrams showing specific circuit examples of a switch circuit according to an embodiment of the present invention;

FIGS. 9A to 9D are diagrams showing other specific circuit examples of the switch circuit according to an embodiment of the present invention; and

FIGS. 10A and 10B are diagrams showing specific circuit examples of a constant current source I3 according to an embodiment of the present invention.

### DETAILED DESCRIPTION OF THE PREFERRED EMBODIMENTS

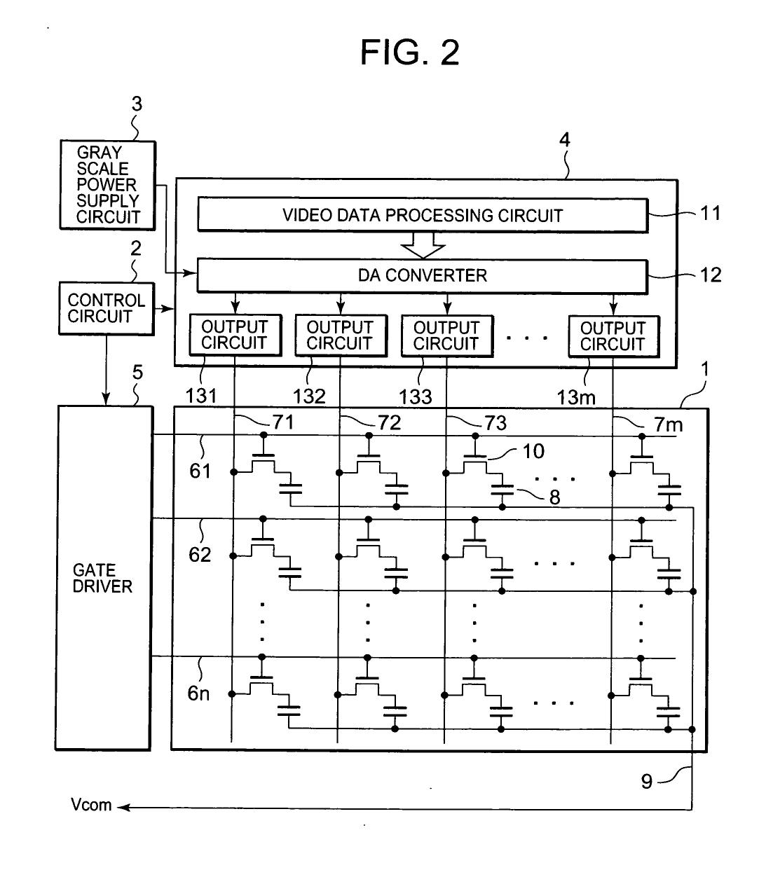

Preferred embodiments of the present invention will now be described with reference to the drawings. FIG. 2 is a block diagram showing a configuration example of a liquid crystal display. The liquid crystal display employs a system in which an analog data signal generated based on digital video data is applied to a liquid crystal panel. The liquid crystal display is provided with: a liquid crystal panel 1; a control circuit 2; a gray scale power supply circuit 3; a data electrode drive circuit (source driver) 4; and a scanning electrode drive circuit (gate driver) 5.

The liquid crystal panel 1 employs an active matrix driving system and uses a thin film transistor (TFT) as a switch element. The liquid crystal panel 1 assumes, as pixels, a region enclosed by n-number (where n is a natural number) of scanning electrodes (gate lines) 61 to 6n provided at predetermined intervals in a row direction and m-number (where m is a natural number) of data electrodes (source lines) 71 to 7m provided at predetermined intervals in a column direction. Accordingly, there are (n×m) number of pixels in the entire display screen. Each pixel of the liquid crystal panel 1 is provided with: a liquid crystal capacitance 8 that is equivalently a capacitive load; a common electrode 9; and a TFT 10 that drives the corresponding liquid crystal capacitance 8.

When driving the liquid crystal panel 1, a common voltage Vcom is applied to the common electrode 9. In this state, an analog data signal generated based on digital video data is applied to the data electrodes 71 to 7m. In addition, a gate pulse generated based on a horizontal synchronizing signal and a vertical synchronizing signal is applied to the scanning electrodes 61 to 6n. Accordingly, characters, images and the like are displayed on the display screen of the liquid crystal panel 1. In the case of color display, red, green, and blue signals of analog data are generated based on red, green, and blue digital video data, whereby the red, green, and blue signals are to be respectively applied to corresponding data electrodes. Although the amount of information and required circuits are tripled in color display, since there is no direct bearing on operations, descriptions on color are hereby omitted.

The control circuit 2 is configured by, for example, an ASIC (application specific integrated circuit) or the like, and a dot clock signal, a horizontal synchronizing signal and a vertical synchronizing signal, a data enable signal, and the like are supplied thereto from the outside. Based on these signals, the control circuit 2 generates a strobe signal, a clock signal, a horizontal scanning pulse signal, a polarity signal, a vertical scanning pulse signal, and the like, and supplies the signals to the source driver 4 and the gate driver 5. A strobe signal is a signal having the same period as a horizontal synchronizing signal. In addition, a clock signal is a signal that synchronizes with a dot clock signal and has either the same or a different frequency. A clock signal is used to generate a sampling pulse from a horizontal scanning pulse signal or the like by a shift register included in the source driver 4. A horizontal scanning pulse signal is a signal having the same period as a horizontal synchronizing signal, but delayed from a strobe signal by several periods of a clock signal. Furthermore, a polarity signal is a signal that is reversed each horizontal period, i.e., each line, in order to AC-drive the liquid crystal panel 1. The polarity signal also reverses each vertical synchronization period. A vertical scanning pulse signal is a signal having the same period as a vertical synchronizing signal.

The gate driver 5 sequentially generates gate pulses in synchronization with the timings of vertical scanning pulse signals supplied from the control circuit 2. The gate driver 5 sequentially applies the generated gate pulses to corresponding scanning electrodes 61 to 6n of the liquid crystal panel 1.

The gray scale power supply circuit 3 is provided with: a plurality of resistors cascade-connected between a reference voltage and ground; and a plurality of voltage followers whose respective input terminals are connected to connecting points of adjacent resistors. The gray scale power supply circuit 3 amplifies and buffers a gray scale voltage appearing at connecting points of adjacent resistors, and supplies the same to the source driver 4. The gray scale voltage is set so that correction of gamma conversion is performed. Originally, gamma conversion refers to performing correction so as to achieve the opposite of the characteristics of a traditional imaging tube, thereby consequently restoring a normal visual signal. With the gamma conversion in the present case, the gamma of the entire system is assumed to be 1, and an analog video signal or a digital video signal is corrected to obtain a playback image with a favorable gray scale. Generally, gamma conversion is performed on an analog video signal or a digital video signal so as to conform the signal to the characteristics of a CRT display or, in other words, to achieve compatibility thereof.

As shown in FIG. 2, the source driver 4 is provided with: a video data processing circuit 11; a digital-analog converter (DAC) 12; and m-number of output circuits 131 to 13m.

The video data processing circuit 11 is provided with a shift register, a data register, a latch circuit, and a lever shifter circuit (not shown). The shift register is a serial-in parallel-out shift register made up of a plurality of delay flip-flops. The shift register performs a shift operation in which a horizontal scanning pulse signal supplied from the control circuit 2 is shifted in synchronization with a clock signal supplied from the control circuit 2, and outputs a parallel sampling pulse of a plurality of bits. The data register loads data of a digital video data signal supplied from the outside as display data in synchronization with a sampling pulse supplied from the shift register, and supplies the same to the latch circuit. The latch circuit loads the display data supplied from the data register in synchronization with a rise of a strobe signal supplied from the control circuit 2. The latch circuit retains the loaded display data until the strobe signal rises next or, in other words, for one horizontal period. The level shifter circuit converts the voltage of output data of the latch circuit and outputs the same as voltage conversion display data.

Based on a gray scale voltage supplied from the gray scale power supply circuit 3, the digital-analog converter 12 assigns gamma-corrected gray scale characteristics on voltage conversion display data supplied from the video data processing circuit 11. Therefore, the digital-analog converter 12 converts gamma-corrected data to analog data signals and supplies the same to corresponding output circuits 131 to 13m.

The output circuits 131 to 13m are circuits sharing the same configuration and are collectively referred to as, simply, an output circuit 13. In addition, the data electrodes (source lines) 71 to 7m are collectively referred to as, simply, a data electrode 7. The output circuit 13 is provided with a voltage follower and a switch, and drives the data electrode 7. An operational amplifier circuit according to the present invention is to be used in the voltage follower.

### First Embodiment

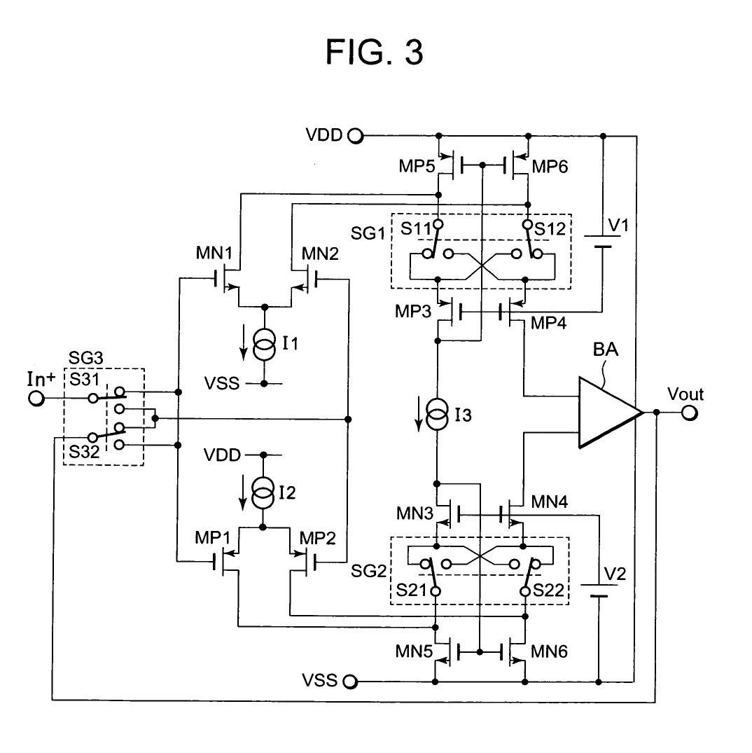

FIG. 3 is a circuit diagram showing an equivalent circuit of a differential amplifier circuit according to a first embodiment of the present invention. A description will now be given based on FIG. 3.

A differential amplifier circuit according to the present invention is provided with: N-channel MOS transistors MN1 and MN2 which form an N-channel receiving differential pair; N-channel MOS transistors MN3 to MN6; P-channel MOS transistors MP1 and MP2 which form a P-channel receiving differential pair; P-channel MOS transistors MP3 to MP6; switch groups SG1 to SG3; constant current sources I1 to I3; constant voltage sources V1 and V2; and an output buffer amplifier BA.

The N-receiving differential pair transistors MN1 and MN2 form an input differential stage. Respective sources thereof are commonly connected to each other, and connected via the constant current source I1 to a negative power supply voltage VSS. Respective gates thereof are commonly connected to respective gates of the P-receiving differential pair transistors MP1 and MP2. A drain of the N-channel MOS transistor MN1 is connected to a drain of the P-channel MOS transistor MP5. A drain of the N-channel MOS transistor MN2 is connected to a drain of the P-channel MOS transistor MP6. The P-receiving differential pair transistors MP1 and MP2 similarly form an input differential stage. Respective sources thereof are commonly connected to each other, and connected via the constant current source I2 to a positive power supply voltage VDD. A drain of the P-channel MOS transistor MP1 is connected to a drain of the N-channel MOS transistor MN5. A drain of the P-channel MOS transistor MP2 is connected to a drain of the N-channel MOS transistor MN6.

Respective sources and respective gates of the P-channel MOS transistors MP5 and MP6 are commonly connected to each other. The sources are connected to the positive power supply voltage VDD, while drains thereof are connected to the respective drains of the N-receiving differential pair transistors MN1 and MN2. The P-channel MOS transistors MP5 and MP6 function as active loads of a folded cascode connection. Similarly, respective sources and respective gates of the N-channel MOS transistors MN5 and MN6 are commonly connected to each other. The sources are connected to the negative power supply voltage VSS, while drains thereof are connected to the respective drains of the P-receiving differential pair transistors MP1 and MP2. The N-channel MOS transistors MN5 and MN6 function as active loads of a folded cascode connection.

Respective gates of the P-channel MOS transistors MP3 and MP4 are commonly connected to each other and are both connected to the constant voltage source V1. Sources of the P-channel MOS transistors MP3 and MP4 are connected via the switch group SG1 to the drains of the P-channel MOS transistors MP5 and MP6. A drain of the P-channel MOS transistor MP3 is connected to a drain of the N-channel MOS transistor MN3 via commonly-connected gates of the P-channel MOS transistors MP5 and MP6 and the constant current source I3.

Respective gates of the N-channel MOS transistors MN3 and MN4 are commonly connected to each other and are both connected to the constant voltage source V2. Respective sources of the N-channel MOS transistors MN3. and MN4 are connected via the switch group SG2 to the drains of the N-channel MOS transistors MN5 and MN6. The drain of the N-channel MOS transistor MN3 is connected to the drain of the P-channel MOS transistor MP3 via commonly-connected gates of the N-channel MOS transistors MN5 and MN6 and the constant current source I3.

The switch group SG1 is provided with interlocking switches S11 and S12, and is connected between the respective drains of the P-channel MOS transistors MP5 and MP6 and the respective sources of the P-channel MOS transistors MP3 and MP4. The switch S11 switches the connection destination of the drain of the P-channel MOS transistor MP5 to either of the sources of the P-channel MOS transistors MP3 and MP4. The switch S12 switches the connection destination of the drain of the P-channel MOS transistor MP6 to either of the sources of the P-channel MOS transistors MP3 and MP4. Therefore, when the drain of the P-channel MOS transistor MP5 is connected to the source of the P-channel MOS transistor MP3, the drain of the P-channel MOS transistor MP6 is connected to the source of the P-channel MOS transistor MP4. Similarly, when the drain of the P-channel MOS transistor MP5 is connected to the source of the P-channel MOS transistor MP4, the drain of the P-channel MOS transistor MP6 is connected to the source of the P-channel MOS transistor MP3.

The switch group SG2 is provided with interlocking switches S21 and S22, and is connected between the respective drains of the N-channel MOS transistors MN5 and MN6 and the respective sources of the N-channel MOS transistors MN3 and MN4. The switch S21 switches the connection destination of the drain of the N-channel MOS transistor MN5 to either of the sources of the N-channel MOS transistors MN3 and MN4. The switch S22 switches the connection destination of the drain of the N-channel MOS transistor MN6 to either of the sources of the N-channel MOS transistors MN3 and MN4. Therefore, when the drain of the N-channel MOS transistor MN5 is connected to the source of the N-channel MOS transistor MN3, the drain of the N-channel MOS transistor MN6 is connected to the source of the N-channel MOS transistor MN4. Similarly, when the drain of the N-channel MOS transistor MN5 is connected to the source of the N-channel MOS transistor MN4, the drain of the N-channel MOS transistor MN6 is connected to the source of the N-channel MOS transistor MN3.

The switch group SG3 is provided with: a switch S31 whose common node is connected to an input node In+; and a switch S32 whose common node is connected to an output node Vout. A make node of the switch S31 is connected to a common connection node of one of the gates of the N-receiving differential pair transistors and one of the gates of the P-receiving differential pair transistors. A break node of the switch S31 is connected to a common connection node of the other gate of the N-receiving differential pair transistors and the other gate of the P-receiving differential pair transistors. A make node of the switch S32 is connected to the break node of the switch S31 and a break node of the switch S32 is connected to the make node of the switch S31. In other words, differential pair transistors to be connected to the input node In+ and the output node Vout are switched by the switches S31 and S32.

For example, the make node of the switch S31 and the break node of the switch S32 are connected to the gate of the N-channel MOS transistor MN1 and the gate of the P-channel MOS transistor MP1, while the break node of the switch S31 and the make node of the switch S32 are connected to the gate of the N-channel MOS transistor MN2 and the gate of the P-channel MOS transistor MP2.

The constant current source I1 is connected between commonly connected sources of the N-receiving differential pair transistors MN1 and MN2 and the negative power supply voltage VSS. The constant current source I2 is connected between commonly connected sources of the P-receiving differential pair transistors MP1 and MP2 and the positive power supply voltage VDD. The constant current source I3 is a floating current source whose one end is commonly connected to the drain of the P-channel MOS transistor MP3 and the gates of the P-channel MOS transistors MP5 and MP6. The other end of the constant current source I3 is commonly connected to the drain of the N-channel MOS transistor MN3 and the gates of the N-channel MOS transistors MN5 and MN6.

The constant voltage source V1 is connected between the commonly connected gates of the P-channel MOS transistors MP3 and MP4 and the positive power supply voltage VDD. The constant voltage source V2 is connected between the commonly connected gates of the N-channel MOS transistors MN3 and MN4 and the negative power supply voltage VSS. The output buffer amplifier BA is an output buffer circuit having one input node thereof connected to a drain of the P-channel MOS transistor MP4 and the other input node connected to a drain of the N-channel MOS transistor MN4.

Next, operations of the present differential amplifier circuit will be described. In this case, the switch groups SG1 to SG3 are controlled so as to be collectively interlocked. Therefore, the switch groups have only two operational states. The switch group SG1 switches an offset voltage generated due to threshold voltage (VT) variations of the P-channel MOS transistors MP5 and MP6 that are active loads. In a similar manner, the switch group SG2 switches an offset voltage generated due to threshold voltage (VT) variations of the N-channel MOS transistors MN5 and MN6 that are active loads. Furthermore, the switch group SG3 switches between an offset voltage generated due to threshold voltage (VT) variations of the N-receiving differential pair transistors MN1 and MN2 and an offset voltage generated due to threshold voltage (VT) variations of the P-receiving differential pair transistors MP1 and MP2.

In such a circuit architecture, most of the offset voltage of an amplifier circuit is determined by the following four variation factors. That is, (1) the threshold voltage (VT) variations of the active load made up of the P-channel MOS transistors MP5 and MP6, (2) the threshold voltage (VT) variations of the active load made up of the N-channel MOS transistors MN5 and MN6, (3) the threshold voltage (VT) variations of the N-receiving differential pair transistors MN1 and MN2, and (4) the threshold voltage (VT) variations of the P-receiving differential pair transistors MP1 and MP2. Therefore, offset voltages generated by these four factors are respectively switched to reverse polarities with respect to an ideal voltage by switching the switch groups SG1 to SG3 as described above. In other words, if the offset voltage generated by these four factors is denoted by Vos and an input voltage by VIN, then an output voltage VO generated each time a switch is switched may be expressed as VO=VIN±Vos. In this case, depending on the two states of the switch groups, a polarity denoted by “±” becomes “+” in one of the switch states and “−” in the other switch state. The polarity differs according to the intrinsic offset voltage of the amplifier circuit.

Consequently, by switching the switch groups SG1 to SG3, offset voltage is averaged and an ideal voltage is to be outputted.

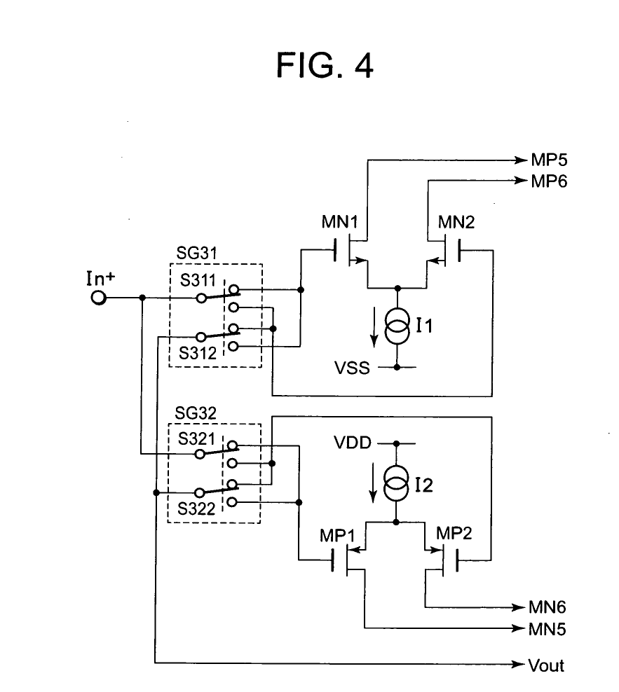

The switch group SG3 is provided with: a switch S31 that switches a connection destination of a signal inputted from the non-inversion input node In+ to either the transistors MN1 and MP1 or the transistors MN2 and MP2; and a switch S32 that switches a connection destination of a signal outputted from the output node Vout to either the transistors MN1 and MP1 or the transistors MN2 and MP2. As shown in FIG. 4, the circuit may be provided with separated switches for each differential pair. That is, the switch group SG3 may be provided with: a switch group SG31 that switches the inputs of the N-receiving differential pair transistors MN1 and MN2; and a switch group SG32 that switches the inputs of the P-receiving differential pair transistors MP1 and MP2. In this case, the switch group SG31 is provided with: a switch S311 that switches a connection destination of a signal inputted from the non-inversion input node In+; and a switch S312 that switches a connection destination of a signal outputted from the output node Vout. In addition, the switch group SG32 is provided with: a switch S321 that switches a connection destination of a signal inputted from the non-inversion input node In+; and a switch S322 that switches a connection destination of a signal outputted from the output node Vout. These switch groups interlockingly switch connections so as to average offset voltage.

### Second Embodiment

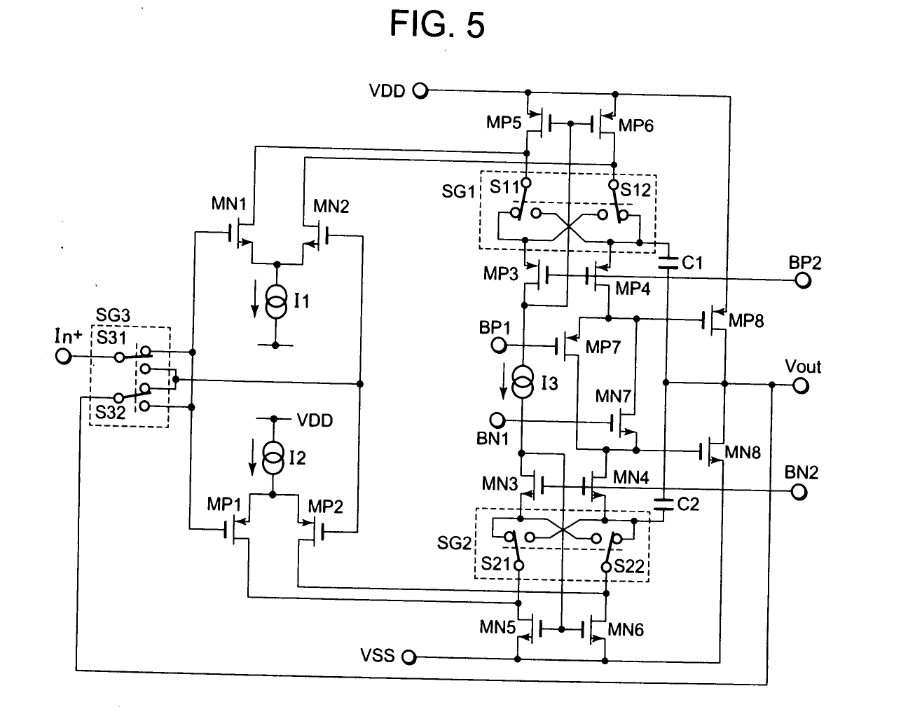

FIG. 5 shows an example of a realization of the output buffer amplifier BA shown in FIG. 3. Descriptions of like parts to FIG. 3 are hereby omitted. As shown in FIG. 5, the output buffer amplifier BA is provided with: a P-channel MOS transistor MP8; an N-channel MOS transistor MN8; a P-channel MOS transistor MP7; an N-channel MOS transistor MN7; a capacitance C1; and a capacitance C2. Constant voltage sources V1 and V2 are assumed to be respectively connected to constant voltage source nodes BP2 and BN2, and depictions thereof are omitted.

A gate of the P-channel MOS transistor MP8 is connected to the drain of the P-channel MOS transistor MP4 as one of the input nodes of the output buffer amplifier BA, a source thereof is connected to the positive power source VDD, and a drain thereof is connected to the output node Vout of the output buffer amplifier BA. A gate of the N-channel MOS transistor MN8 is connected to the drain of the N-channel MOS transistor MN4 as the other input node of the output buffer amplifier BA, a source thereof is connected to the negative power source VSS, and a drain thereof is connected to the output node Vout of the output buffer amplifier BA.

A gate of the P-channel MOS transistor MP7 is connected to a constant voltage source node BP1, a source thereof is connected to the gate of the P-channel MOS transistor MP8, and a drain thereof is connected to the gate of the N-channel MOS transistor MN8. The P-channel MOS transistor MP7 determines an idling current of the P-channel MOS transistor MP8.

A gate of the N-channel MOS transistor MN7 is connected to a constant voltage source node BN1, a source thereof is connected to the gate of the N-channel MOS transistor MN8; and a drain thereof is connected to the gate of the P-channel MOS transistor MP8. The N-channel MOS transistor MN7 determines an idling current of the N-channel MOS transistor MN8.

The capacitance C1 functions as a phase compensation capacitance whose one end is connected to the source of the P-channel MOS transistor MP4 and the other end is connected to the output node Vout. The capacitance C2 similarly functions as a phase compensation capacitance whose one end is connected to the source of the N-channel MOS transistor MN4 and the other end is connected to the output node Vout.

The N-channel MOS transistor MN8 and the P-channel MOS transistor MP8 function as a so-called floating constant current source. A method of setting the floating constant current source will be described below.

Since a voltage V(BP1) of the constant voltage source connected to the node BP1 is equal to the sum of a voltage VGS(MP7) between the gate and the source of the P-channel MOS transistor MP7 and a voltage VGS(MP8) between the gate and the source of the P-channel MOS transistor MP8, formula (1) below is true.

V(BP1)=VGS(MP7)+VGS(MP8) (1)

In addition, if a gate width of a transistor is denoted by W, a gate length by L, mobility by μ, a gate oxide film capacitance per unit area by C0, a threshold voltage by VT, and a drain current by ID, then a gate-source voltage VGS may be expressed by the following formula:

$$\begin{matrix}[ Formula 1 ] & \\ {V}_{GS} = \sqrt{\frac{2 {I}_{D}}{β}} + {V}_{T} \\ where β = \frac{W}{L} μ {C}_{O} & ( 2 )\end{matrix}$$

When the N-channel MOS transistors MN1 and MN2 making up a differential pair operate as an amplifier, the drain currents of both transistors are equal to one another. Therefore, if a current of the current source I3 is denoted by I3, then respective drain currents thereof can be denoted by I3/2. Typically, a bias voltage to be applied to the nodes BP1 and BN1 are determined such that the drain currents of the P-channel MOS transistor MP7 and the N-channel MOS transistor MN7 making up a floating current source become equal to one another. At this point, the relationship between an idling current Iidle(MP8) of the P-channel MOS transistor MP8 of an output stage and the bias voltage V(BP1) of the node BP1 may be expressed by the following formula. In the formula, β(MP7) denotes β of the P-channel MOS transistor MP7 and β(MP8) denotes β of the P-channel MOS transistor MP8.

$$\begin{matrix}[ Formula 2 ] & \\ {V}_{( BP 1 )} = \sqrt{\frac{{I}_{3}}{{β}_{( MP 7 )}}} + \sqrt{\frac{2 {I}_{idle ( MP 8 )}}{{β}_{( MP 8 )}}} + 2 {V}_{T} & ( 3 )\end{matrix}$$

Although a specific circuit of a constant voltage source for generating the bias voltage V(BP1) will not be indicated herein, formula (3) can be solved for Iidle(MP8). As the actual formula is extremely complex, the equation will be hereby omitted.

Similarly, a voltage V(BN1) of a constant voltage source connected to the node BN1 is set such that the drain current of the N-channel MOS transistor MN7 and the drain current of the P-channel MOS transistor MP7 become equal to one another.

The floating constant current source is set as described above. In this case, the constant voltage source (voltage V(BN1)) connected to the node BN1 and the constant voltage source (voltage V(BP1)) connected to the node BP1 include two MOS transistors and a constant current source and are therefore more resistant to fluctuations due to element variations. According to the, configuration above, a term “2VT” appears in a formula that expands V(BP1) along the circuit. Since the left side (V(BP1)) of the formula (3) described above includes the same term “2VT” that is included in the right side, the term is cancelled from the left and right sides. A specific circuit example of a constant voltage source is not depicted.

### Third Embodiment

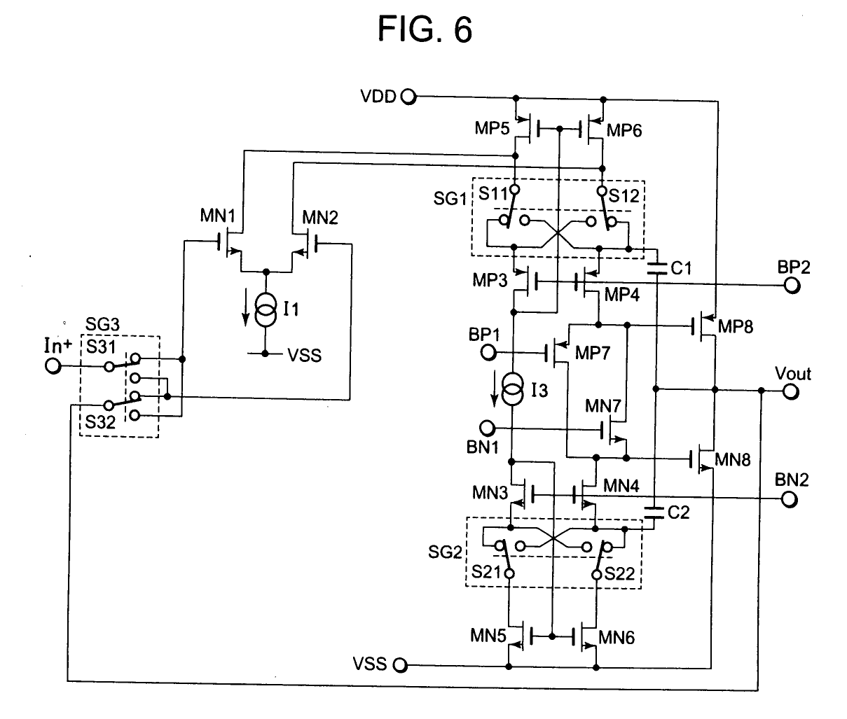

FIG. 6 is a diagram of a circuit in which the P-channel receiving differential stage shown in FIG. 5 is omitted.

The P-channel receiving differential stage shown in FIG. 5 is unnecessary when a rail-to-rail characteristic is not required and the input voltage ranges from about Vss+1 volt to VDD. Therefore, in this case, it is possible to omit the P-channel MOS transistors MP1 and MP2 making up the P-channel receiving differential pair and the constant current source I2 shown in FIG. 5. Normal operations of an amplifier can be performed even if these elements are omitted. Circuit operations are basically the same as those of the circuit shown in FIG. 5 described above. As such, a description of operations thereof is omitted.

### Fourth Embodiment

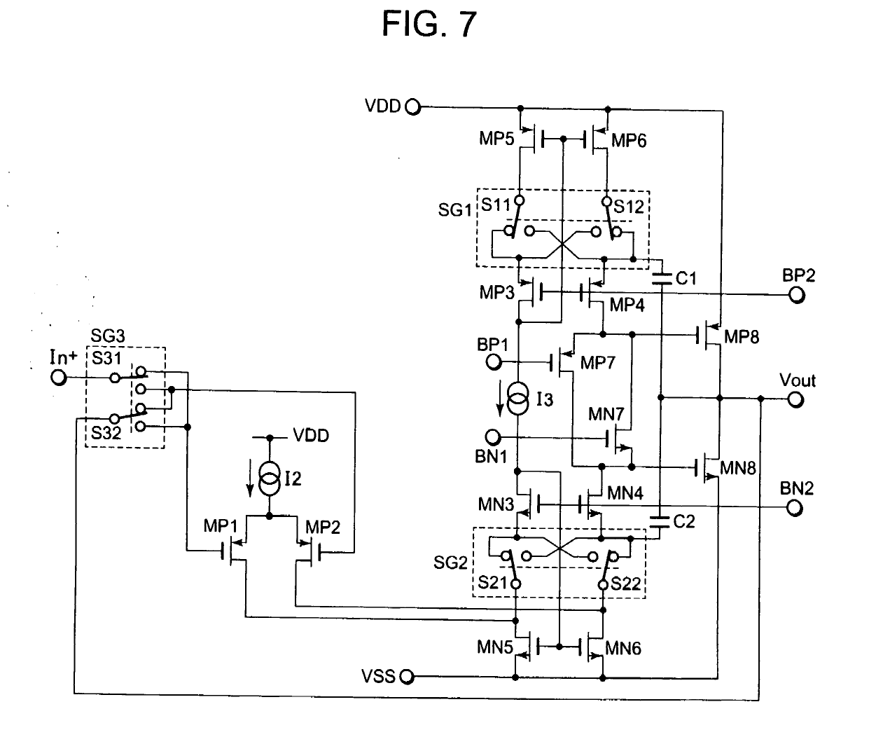

FIG. 7 is a diagram showing a circuit in which the N-channel receiving differential stage shown in FIG. 5 is omitted.

The N-channel receiving differential stage shown in FIG. 5 is unnecessary when a rail-to-rail characteristic is not required and the input voltage ranges from Vss to about VDD-1 volt. Therefore, in this case, it is possible to omit the N-channel MOS transistors MN1 and MN2 making up the N-channel receiving differential pair and the constant current source I1 shown in FIG. 5. Normal operations of an amplifier can be performed even if these elements are omitted. Circuit operations are basically the same as those of the circuit shown in FIG. 5 described above. As such, a description of operations thereof is omitted.

### Fifth Embodiment

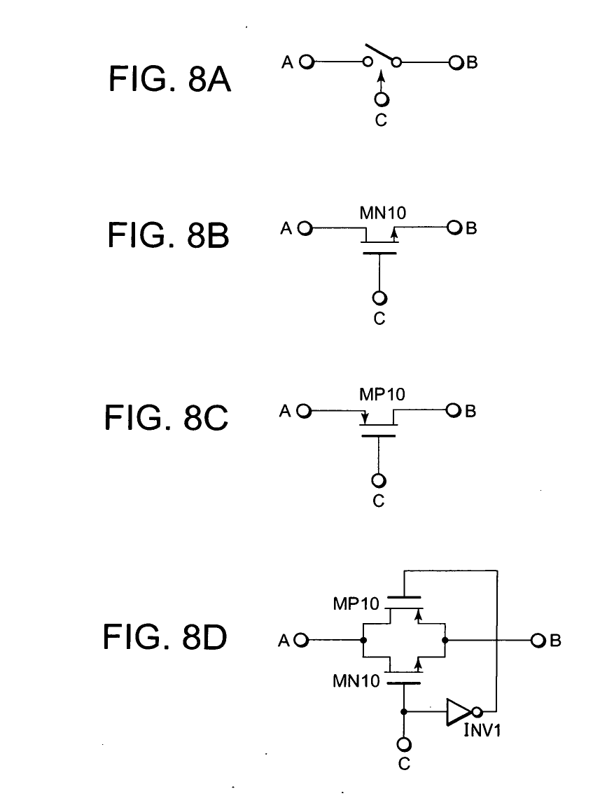

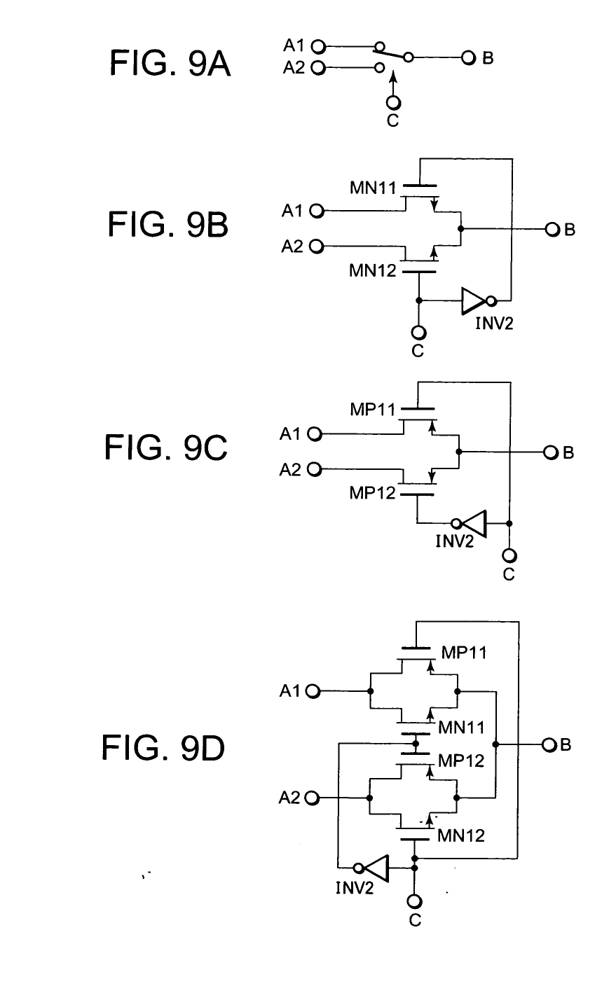

Next, a specific example of realizing the aforementioned switches will be described with reference to FIGS. 8 and 9. First, terminology will be clarified. A “make switch” refers to a switch that closes a circuit when a control signal is being inputted. In addition, a “break switch” refers to a switch that opens a circuit when a control signal is being inputted. Furthermore, a “transfer switch” is a switch provided with a common node and two output nodes (make-side and break-side). With a transfer switch, a conduction state is created between the common node and the make node when a control signal is being inputted, and a conduction state is created between the common node and the break node when a control signal is not being inputted.

FIG. 8 shows a make-and-break switch. As shown in FIG. 8A, the switch controls a short-circuit/open-circuit between nodes A and B according to a signal applied to a node C. The switch is realized by an N-channel MOS transistor MN10 (FIG. 8B) or a P-channel MOS transistor MP10 (FIG. 8C). Nodes A and B correspond to a drain and a source of the N-channel MOS transistor MN10 or the P-channel MOS transistor MP10, and a short-circuit/open-circuit of the switch is controlled by applying a control signal to a gate corresponding to the node C. As shown in FIG. 8B, in the case of an N-channel MOS transistor, the drain-source section enters a conduction state when the gate is at a high level. In other words, the switch is closed. The drain-source section enters a non-conduction state when the gate is at a low level, whereby the switch is opened. As shown in FIG. 8C, in the case of a P-channel MOS transistor, the switch conversely closes when the gate is at a low level and opens when the gate is at a high level.

Furthermore, as shown in FIG. 8D, there is also a switch that combines an N-channel MOS transistor and a P-channel MOS transistor. With the switch, respective drains and respective sources of the N-channel MOS transistor MN10 and the P-channel MOS transistor MP10 are commonly connected to each other, while respective gates thereof are driven under an antiphase signal by an inverter INV1. In this case, when the gate of the N-channel MOS transistor MN10 is at a high level, the inverter INV1 causes the gate of the P-channel MOS transistor MP10 to assume a low level, whereby both transistors enter a conduction state. In other words, the switch is turned on (closed). Conversely, when the gate of the N-channel MOS transistor MN10 is at a low level, the inverter INV1 causes the gate of the P-channel MOS transistor MP10 to assume a high level, whereby both transistors enter a non-conduction state. In other words, the switch is turned off (opened).

Moreover, as shown in FIG. 9A, a transfer switch is provided with: a break node A1; a make node A2; a common node B; and a node C to which a control signal is inputted.

As shown in FIG. 9B, the transfer switch commonly connects the respective sources of two N-channel MOS transistors MN11 and MN12 to form a transfer switch common node. Drains of the N-channel MOS transistors MN11 and MN12 respectively become the break node A1 and the make node A2. Gates of the respective transistors are driven in opposite phase by an inverter INV2. That is, when the gate of one of the transistor is at a high level, the gate of the other transistor assumes a low level. Therefore, either one of the nodes A1 and A2 enters a conduction state with the common node B while the other node enters a non-conduction state.

In addition, as shown in FIG. 9C, a transfer switch using two P-channel MOS transistors MP11 and MP12 similarly commonly connects the respective sources of the two P-channel MOS transistors MP11 and MP12 to form a transfer switch common node B. Drains of the P-channel MOS transistors MP11 and MP12 respectively become the break node A1 and the make node A2. Respective gates of the two P-channel MOS transistors MP11 and MP12 are driven in opposite phase by the inverter INV2.

Furthermore, FIG. 9D shows a transfer switch in the case of using a circuit that combines an N-channel MOS transistor and a P-channel MOS transistor. A commonly connected drain of the N-channel MOS transistor MN11 and the P-channel MOS transistor MP11 is connected to the break node A1 and a commonly connected drain of the N-channel MOS transistor MN12 and the P-channel MOS transistor MP12 is connected to the make node A2. The sources of the four transistors are commonly connected to become the transfer switch common node B. The gate of the N-channel MOS transistor MN12 and the gate of the P-channel MOS transistor MP11 are commonly connected to each other and are connected to the control node C. The gate of the N-channel MOS transistor MN11 and the gate of the P-channel MOS transistor MP12 are commonly connected to each other and are connected to the control node C via the inverter INV2. Therefore, the N-channel MOS transistor MN12 and the P-channel MOS transistor MP12 connected to the make node A2 are driven in opposite phase to the N-channel MOS transistor MN11 and the P-channel MOS transistor MP11 connected to the break node. Since operations of the transfer switch are basically a combination of the make and break switches described above, a description thereof will be omitted.

A method of selecting the aforementioned switches will now be described. Whether an N-channel MOS transistor, a P-channel MOS transistor, or a circuit combining an N-channel MOS transistor and a P-channel MOS transistor is used as a switch is to be judged depending on a voltage applied to the switch. For example, if a positive power supply voltage is denoted by VDD and a negative power supply voltage by VSS, a P-channel MOS transistor is likely to be used when the voltage applied to the switch is higher than (VDD−VSS)/2. Conversely, an N-channel MOS transistor is likely to be used when the voltage applied to the switch is lower than (VDD−VSS)/2. Furthermore, in cases where operations must take place in the entire input voltage range from VSS to VDD, a circuit combining an N-channel MOS transistor and a P-channel MOS transistor is to be used.

In the circuit example shown in FIG. 3, since the switch group SG3 must be operated in the entire input voltage range from VSS to VDD, it is necessary to use a switch such as that shown in FIG. 9D in which a circuit combines an N-channel MOS transistor and a P-channel MOS transistor. In addition, since a switch of the switch group SG1 handles signals of a voltage that is approximately 1 to 2 volts lower than the voltage VDD, a P-channel MOS transistor is used as the switch for the switch group SG1. Furthermore, since a switch of the switch group SG2 handles signals of a voltage that is approximately 1 to 2 volts higher than the voltage VSS(GND), an N-channel MOS transistor is used as the switch for the switch group SG2.

### Sixth Embodiment

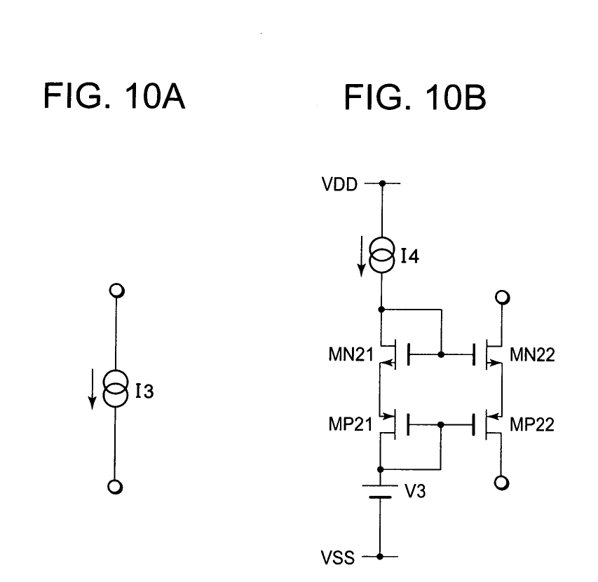

Next, a specific circuit example of the constant current source I3 described in the first to fourth embodiments will be shown. Since a voltage of both ends of the constant current source I3 can be set without limitation, the constant current source I3 is otherwise referred to as a “floating current source”. For example, as shown in FIG. 10, a floating current source is provided with: N-channel MOS transistors MN21 and MN22; P-channel MOS transistors MP21 and MP22; a constant voltage source V3; and a constant current source I4.

Respective gates of the N-channel MOS transistors MN21 and MN22 are commonly connected to each other and further connected to a drain of the N-channel MOS transistor MN21. The drain of the N-channel MOS transistor MN21 is connected to the positive power supply voltage VDD via the constant current source I4, while a source thereof is connected to a source of the P-channel MOS transistor MP21. A drain of the N-channel MOS transistor MN22 becomes a current input node of the floating constant current source I3, while a source thereof is connected to a source of the P-channel MOS transistor MP22.

Respective gates of the P-channel MOS transistors MP21 and MP22 are commonly connected to each other and further connected to the drain of the P-channel MOS transistor MP21. The drain of the P-channel MOS transistor MP21 is connected to the negative power supply voltage VSS via the constant current source I3, while a source thereof is connected to the source of the N-channel MOS transistor MN21. A drain of the P-channel MOS transistor MP22 becomes a current output node of the floating constant current source I3, while the source thereof is connected to the source of the N-channel MOS transistor MN22.

A high voltage-side node of the constant voltage source V3 is connected to the gate and the drain of the P-channel MOS transistor MP21 while a low voltage-side node thereof is connected to the negative power supply voltage VSS. The constant current source I4 is inserted between the positive power supply voltage VDD and the gate and the drain of the N-channel MOS transistor MN21, and supplies a constant current.

Next, operations of the floating current source I3 will be described. Strictly speaking, there is a mode in which a current partially leaks from a drain to a substrate depending on a gate-source voltage. However, with a MOS transistor, a drain current is basically equal to a source current. Therefore, the serially-connected N-channel MOS transistor MN21 and P-channel MOS transistor MP21 respectively operate under the same drain current. In other words, a current I4 supplied from the constant current source I4 becomes the drain currents of the respective transistors. Similarly, the respective drain currents of the serially-connected N-channel MOS transistor MN22 and P-channel MOS transistor MP22 are equal to one another.

The constant voltage source V3 provides a bias voltage that determines operating voltages of the P-channel MOS transistor MP21 and the N-channel MOS transistor MN21. The voltage of the constant voltage source V3 is optimally determined such that a source voltage of the P-channel MOS transistor MP21 becomes exactly equal to VDD/2. In this case, it is assumed that the N-channel MOS transistor MN22 and the N-channel MOS transistor MN21 are, configured with the same gate width W/gate length L dimensions, and that the P-channel MOS transistor MP21 and the P-channel MOS transistor MP22 are configured with the same gate width W/gate length L dimensions. The sum of a voltage (VGS(MP21)) applied to the gate-source section of the P-channel MOS transistor MP21 and a voltage (VGS(MN21)) applied to the gate-source section of the N-channel MOS transistor MN21 becomes equal to the sum of a voltage (VGS(MP22)) applied to the gate-source section of the P-channel MOS transistor MP22 and a voltage (VGS(MN22)) applied to the gate-source section of the N-channel MOS transistor MN22. This equation may be expressed as:

VGS(MN21)+VGS(MP21)=VGS(MN22)+VGS(MP22) (4)

Since the gate-source voltage can be expressed as formula (2) as described earlier,

$$\begin{matrix}[ Formula 3 ] & \\ \sqrt{\frac{2 {I}_{4}}{{β}_{( MN 21 )}}} + \sqrt{\frac{2 {I}_{4}}{{β}_{( MP 21 )}}} = \sqrt{\frac{2 {I}_{D ( MN 22 )}}{{β}_{( MN 22 )}}} + \sqrt{\frac{2 {I}_{D ( MP 22 )}}{{β}_{( MP 22 )}}} & ( 5 )\end{matrix}$$

holds true, where βP(MXn) denotes β of an X-channel MOS transistor MXn.

In addition, since the drain current (ID(MN22)) of the N-channel MOS transistor MN22 and the drain current (ID(MP22)) of the P-channel MOS transistor MP22 are equal to one another, consequently,

ID(MN22)=ID(MP22)−I4 (6)

holds true, thereby realizing a floating constant current source.

While the circuit described above has been exemplified herein, another circuit architecture is shown in Japanese Patent Laid-Open No. 2006-319921. In the present invention, the floating current source I3 is not limited to the circuit architecture described above and alternative configurations may be adopted.

The operational amplifier circuit according to the present invention is suitable as an output amplifier of an LCD source driver or an operational amplifier used in a gray scale power supply circuit that determines γ correction. Such operational amplifiers require a circuit with minimal offset voltage, which in turn requires some measures of offsetting cancellation. The present invention realizes a spatial offset cancellation circuit that cancels offset with a simple circuit architecture.

When the operational amplifier according to the present invention is used as an output amplifier of a liquid crystal display source driver or in a gray scale power supply circuit that determines γ correction, switching is performed by a liquid crystal drive signal corresponding to one horizontal period, one frame period, or the like. Accordingly, an offset voltage generated in the operational amplifier is spatially dispersed. As a result, a beautiful image that is superficially free of offset voltage is obtained so as to deceive the human eye. While the presence of an offset voltage creates display defects such as vertical banding, using the operational amplifier circuit according to the present invention enables homogeneous gray scales to be obtained.

What is claimed is:

1. An operational amplifier circuit comprising:
a differential pair section that receives an input signal inputted from a signal input node and an output signal outputted from a signal output node as differential signals;
a first switch section that interchanges the input signal and the output signal and connects the signals to the differential pair section;
a folded cascode-connected current mirror circuit section that becomes an active load of the differential pair, the current mirror circuit section including a load transistor group that functions as an active load of the folded cascode connection and a bias transistor group to which a bias voltage is applied,
a second switch section that switches connections with the load transistor group and the bias transistor group; and
a buffer amplifier that receives a signal outputted from the current mirror circuit section and outputs the output signal, wherein
the operational amplifier circuit interlockingly switches the first switch section and the second switch section to spatially disperse offset voltage and equivalently cancel offset.

2. The operational amplifier circuit according to claim 1, wherein
the load transistor group comprises:
a first load P-channel MOS transistor including a source connected to a positive power supply voltage, a drain connected to the bias transistor group via the second switch section, and a gate connected to the bias transistor group;
a second load P-channel MOS transistor including a source connected to the positive power supply voltage, a drain connected to the bias transistor group via the second switch section, and a gate connected to the gate of the first load P-channel MOS transistor;
a first load N-channel MOS transistor including a source connected to a negative power supply voltage, a drain connected to the bias transistor group via the second switch section, and a gate connected to the bias transistor group; and
a second load N-channel MOS transistor including a source connected to the negative power supply voltage, a drain connected to the bias transistor group via the second switch section, and a gate connected to the gate of the first load N-channel MOS transistor, and
the bias transistor group comprises:
a first bias P-channel MOS transistor and a second bias P-channel MOS transistor whose gates are connected to each other and a common bias voltage is applied thereto; and
a first bias N-channel MOS transistor and a second bias N-channel MOS transistor whose gates are connected to each other and a common bias voltage is applied thereto.

3. The operational amplifier circuit according to claim 2, wherein
the output buffer amplifier comprises:
a first output P-channel MOS transistor including a source connected to the positive power supply voltage, a drain connected to the output node, and a gate connected to the drain of the second bias P-channel MOS transistor;
a first output N-channel MOS transistor including a source connected to the negative power supply voltage, a drain connected to the output node, and a gate connected to the drain of the second bias N-channel MOS transistor;
a second output P-channel MOS transistor including a source connected to the gate of the first output P-channel MOS transistor, a drain connected to the gate of the first output N-channel MOS transistor and a gate to which a predetermined voltage is applied, and which controls an idling current of the first output P-channel MOS transistor;
a second output N-channel MOS transistor including a source connected to the gate of the first output N-channel MOS transistor, a drain connected to the gate of the first output P-channel MOS transistor and a gate to which a predetermined voltage is applied, and which controls an idling current of the first output N-channel MOS transistor;
a first capacitance having one end thereof connected to the source of the second bias P-channel MOS transistor and the other end connected to the output node, and which function as a phase compensation capacitance; and
a second capacitance having one end thereof connected to the source of the second bias N-channel MOS transistor and the other end connected to the output node, and which function as a phase compensation capacitance.

4. The operational amplifier circuit according to claim 2, further comprising
a floating constant current source provided between a connection node of the drain of the first bias P-channel MOS transistor and the gates of the first and second load P-channel MOS transistors and a connection node of the drain of the first bias N-channel MOS transistor and the gates of the first and second load N-channel MOS transistors, and which supplies a constant current to the first bias P-channel MOS transistor and the first bias N-channel MOS transistor, wherein
the floating constant current source comprises:
a constant current source having one end thereof connected to the positive power supply voltage;
a constant voltage source having one end thereof connected to the negative power supply voltage;
a first floating N-channel MOS transistor including a gate and a drain connected to the other end of the constant current source, and a source connected to the negative power supply voltage via the constant voltage source;
a first floating P-channel MOS transistor including a gate and a drain connected to the other end of the constant voltage source, and a source connected to the source of the first floating N-channel MOS transistor;
a second floating N-channel MOS transistor including a gate connected to the gate and the drain of the first floating N-channel MOS transistor, and a drain that becomes a first node that supplies a constant current of the floating constant current source; and
a second floating P-channel MOS transistor including a source connected to a source of the second floating N-channel MOS transistor, a gate connected to the gate and the drain of the first floating P-channel MOS transistor, and a drain that becomes a second node that supplies a constant current of the floating constant current source.

5. The operational amplifier circuit according to claim 2, wherein:
the differential pair section comprises an N-channel receiving differential pair including a first N-channel MOS transistor and a second N-channel MOS transistor; and
the first switch section switches the connection of the input signal and the output signal applied to gates of the first and second N-channel MOS transistors.

6. The operational amplifier circuit according to claim 5, wherein:
a drain of the first N-channel MOS transistor is connected to the drain of the first load P-channel MOS transistor;
a drain of the second N-channel MOS transistor is connected to the drain of the second load P-channel MOS transistor; and
the second switch section comprises
a switch circuit that switches a connection destination of the source of the first bias P-channel MOS transistor between the first load P-channel MOS transistor and the second load P-channel MOS transistor, and
a switch circuit that switches a connection destination of the source of the second bias P-channel MOS transistor between the first load P-channel MOS transistor and the second load P-channel MOS transistor.

7. The operational amplifier circuit according to claim 2, wherein:
the differential pair section comprises a P-channel receiving differential pair including a first P-channel MOS transistor and a second P-channel MOS transistor; and
the first switch section switches the connection of the input signal and the output signal applied to gates of the first and second P-channel MOS transistors.

8. The operational amplifier circuit according to claim 7, wherein:
a drain of the first P-channel MOS transistor is connected to the drain of the first load N-channel MOS transistor;
a drain of the second P-channel MOS transistor is connected to the drain of the second load N-channel MOS transistor; and
the second switch section comprises
a switch circuit that switches a connection destination of the source of the first bias N-channel MOS transistor between the first load N-channel MOS transistor and the second load N-channel MOS transistor, and
a switch circuit that switches a connection destination of the source of the second bias N-channel MOS transistor between the first load N-channel MbS transistor and the second load N-channel MOS transistor.

9. An operational amplifier circuit comprising:
an N-receiving differential pair including N-channel MOS transistors whose sources are commonly connected to each other and which function as an input differential stage;
a P-receiving differential pair including P-channel MOS transistors whose sources are commonly connected to each other and which function as an input differential stage, the P-channel MOS transistors of the P-receiving differential pair having gates respectively connected to corresponding gates of the N-channel MOS transistors of the N-receiving differential pair;
first and second P-channel MOS transistors having sources commonly connected to each other and connected to a positive power supply voltage, gates commonly connected to each other, drains respectively connected to drains of the N-channel MOS transistors of the N-receiving differential pair, and which function as an active load of a folded cascode connection;
first and second N-channel MOS transistors having sources commonly connected to each other and connected to a negative power supply voltage, gates commonly connected to each other, drains respectively connected to drains of the P-channel MOS transistors of the P-receiving differential pair, and which function as an active load of a folded cascode connection;
third and fourth P-channel MOS transistors to which a predetermined bias voltage is applied, and having gates commonly connected to each other;
third and fourth N-channel MOS transistors to which a predetermined bias voltage is applied, and having gates commonly connected to each other;
a first switch group provided between the drains of the first and second P-channel MOS transistors and the sources of the third and fourth P-channel MOS transistors, which switches and connects the drain of the first P-channel MOS transistor and the source of the third or fourth P-channel MOS transistor, and switches and connects the drain of the second P-channel MOS transistor and the source of the third or fourth P-channel MOS transistor;
a second switch group provided between the drains of the first and second N-channel MOS transistors and the sources of the third and fourth N-channel MOS transistors, which switches and connects the drain of the first N-channel MOS transistor and the source of the third or fourth N-channel MOS transistor, and switches and connects the drain of the second N-channel MOS transistor and the source of the third or fourth N-channel MOS transistor;
a third switch group that switches and connects the gate of a first N-transistor that is one of N-transistors of the N-receiving differential pair and the gate of a first P-transistor that is one of P-transistors of the P-receiving differential pair to an input node or an output node, and switches and connects the gate of a second N-transistor that is the other N-transistor of the N-receiving differential pair and the gate of a second P-transistor that is the other P-transistor of the P-receiving differential pair to the output node or the input node; and
an output buffer amplifier that has the drain of the fourth P-channel MOS transistor connected to a first input node and has the drain of the fourth N-channel MOS transistor connected to a second input node, and outputs a signal to the output node.

10. A driving method of a liquid crystal display using the operational amplifier circuit according to claim 9, the driving method comprising:
a first step in which the gate of the first N-transistor and the gate of the first P-transistor are connected to the input node, the gate of the second N-transistor and the gate of the second P-transistor are connected to the output node, the drain of the first P-channel MOS transistor is connected to the source of the third P-channel MOS transistor, the drain of the second P-channel MOS transistor is connected to the source of the fourth P-channel MOS transistor, the drain of the first N-channel MOS transistor is connected to the source of the third N-channel MOS transistor, and the drain of the second N-channel MOS transistor is connected to the source of the fourth N-channel MOS transistor; and
a second step in which the gate of the first N-transistor and the gate of the first P-transistor are connected to the output node, the gate of the second N-transistor and the gate of the second P-transistor are connected to the input node, the drain of the first P-channel MOS transistor is connected to the source of the fourth P-channel MOS transistor, the drain of the second P-channel MOS transistor is connected to the source of the third P-channel MOS transistor, the drain of the first N-channel MOS transistor is connected to the source of the fourth N-channel MOS transistor, and the drain of the second N-channel MOS transistor is connected to the source of the third N-channel MOS transistor, wherein
the first step and the second step are repeated at the same intervals.

11. A liquid crystal display driving method that drives a liquid crystal display using an operational amplifier circuit comprising:
a differential pair section that receives an input signal inputted from a signal input node and an output signal outputted from a signal output node as differential signals, and that is symmetrically configured;
a first switch section that interchanges the input signal and the output signal and connects the signals to the differential pair section;
a folded cascode-connected current mirror circuit section that becomes an active load of the differential pair, the current mirror circuit section including load transistor groups that function as an active load of a folded cascode connection and bias transistor groups to which a bias voltage is applied; and
a second switch section that switches connections with the load transistor group and the bias transistor group, the driving method comprising:
a first connection step in which the input signal is inputted to a first input node of the differential pair section, the output signal is inputted to a second input node of the differential pair section, a first load transistor group among the load transistor groups is connected with a first bias transistor group among the bias transistor groups, and a second load transistor group among the load transistor groups is connected with a second bias transistor group among the bias transistor groups; and
a second connection step in which the output signal is inputted to the first input node of the differential pair section, the input signal is inputted to the second input node of the differential pair section, the first load transistor group among the load transistor groups is connected with the second bias transistor group among the bias transistor groups, and the second load transistor group among the load transistor groups is connected with the first bias transistor group among the bias transistor groups, wherein
the first step and the second step are repeated at the same intervals to spatially disperse offset voltage and equivalently cancel offset.

12. The liquid crystal display driving method according to claim 11, wherein
the first step and the second step are repeated in synchronization with a synchronization signal of the liquid crystal display.

13. The liquid crystal display driving method according to claim 11, wherein
the same interval is set to one frame period of the liquid crystal display.

14. The liquid crystal display driving method according to claim 11, wherein
the same interval is set to one horizontal period of the liquid crystal display.
